(19) United States
(12) Patent Application Publication
(10) Pub. No.: US 2026/0040873 A1
(43) Pub. Date: Feb. 5, 2026

(54) WAFER MAP GENERATION DEVICE AND METHOD OF OPERATING THE SAME

(71) Applicant: Samsung Electronics Co., Ltd., Suwon-si (KR)

(72) Inventors: ChoHwan OH, Suwon-si (KR); QHwan KIM, Suwon-si (KR); Minkyu KIM, Suwon-si (KR); Seungju KIM, Suwon-si (KR); Jaejoon KIM, Suwon-si (KR); Kyu-Baik CHANG, Suwon-si (KR); Jaehoon JEONG, Suwon-si (KR); Wanju CHO, Suwon-si (KR)

(73) Assignee: Samsung Electronics Co., Ltd., Suwon-si (KR)

(21) Appl. No.: 19/078,518

(22) Filed: Mar. 13, 2025

(30) Foreign Application Priority Data
Aug. 5, 2024 (KR) 10-2024-0104230

(51) Int. Cl. H01L 21/67; H01L 23/544

(52) U.S. Cl. CPC H01L 21/67276; H01L 23/544; H01L 2223/54453

(57) ABSTRACT

A wafer map generation device includes a dimension reducer and a map generator. The dimension reducer is configured to receive a plurality of polarization matrices associated with a plurality of target positions of a target wafer substrate and to generate a plurality of reduction result data through dimension reduction of one or more elements of each of the plurality of polarization matrices. The map generator is configured to generate a wafer map associated with the target wafer substrate based on the plurality of reduction result data.

### CROSS-REFERENCE TO RELATED APPLICATIONS

This application claims priority under 35 U.S.C. § 119 to Korean Patent Application No. 10-2024-0104230 filed on Aug. 5, 2024, in the Korean Intellectual Property Office, the disclosure of which is incorporated by reference herein in its entirety.

### BACKGROUND

Some example embodiments described herein relate to a semiconductor device, and more particularly, relate to a wafer map generation device and/or a method of operating the wafer generation device.

Each of or two or more of a wafer fabrication (FAB) process, a wafer test process, assembly process, a package test process, etc. may be sequentially performed to fabricate a semiconductor device. In the wafer test process, after the FAB process ends, whether dice/chips of the wafer operate normally or whether the dice/chips of the wafer are defective may be tested to determine a yield and/or a reliability of the wafer.

The wafer map may visually show a result of predicting a gradient of the wafer substrate in the FAB process and/or the wafer test process. The wafer map may be generated, in general, by using an electron microscope or by using a structure model for a spectrum result of the semiconductor wafer.

### SUMMARY

Some example embodiments provide a wafer map generation device generating a wafer map at high speed without using an electron microscope and/or without using a structure model for a spectrum result of a semiconductor wafer.

Alternatively or additionally, some example embodiments provide a method of operating the wafer map generation device.

According to some example embodiments, a wafer map generation device includes a dimension reducer and a map generator. The dimension reducer is configured to receive a plurality of polarization matrices associated with a plurality of target positions of a target wafer substrate and to generate a plurality of reduction result data through dimension reduction of one or more elements of each of the plurality of polarization matrices. The map generator is configured to generate a wafer map associated with the target wafer substrate based on the plurality of reduction result data.

Alternatively or additionally according to some example embodiments, in a method of operating a wafer map generation device, a plurality of polarization matrices associated with a plurality of target positions of a target wafer substrate are received. A plurality of reduction result data through dimension reduction of one or more elements of each of the plurality of polarization matrices are generated. A wafer map associated with the target wafer substrate based on the plurality of reduction result data is generated.

Alternatively or additionally according to some example embodiments, in a method of operating a wafer map generation device, a plurality of layers are sequentially stacked on a wafer substrate. A plurality of wafer maps corresponding to a plurality of target wafer substrates are generated by setting the wafer substrate as a target wafer substrate in response to one layer being completely stacked on the wafer substrate. In the generating of the plurality of wafer maps, there are generated a plurality of polarization matrices associated with a plurality of target positions of each of the plurality of target wafer substrates. A plurality of reduction result data is generated through dimension reduction of one or more elements of each of the plurality of polarization matrices. The plurality of wafer maps which are respectively associated with the plurality of target wafer substrates are generated based on the plurality of reduction result data.

### BRIEF DESCRIPTION OF THE FIGURES

The above and other objects and features of some example embodiments will become apparent by describing in detail example embodiments thereof with reference to the accompanying drawings.

FIG. 1 is a block diagram illustrating a wafer map generation device according to some example embodiments.

FIG. 2A is a diagram for describing some example embodiments of a target wafer substrate of FIG. 1.

FIG. 2B is a diagram for describing some example embodiments of a plurality of target positions of a target wafer substrate of FIG. 2A.

FIG. 2C is a diagram for describing lights emitted to any one target position of FIG. 2B and lights reflected from the target position.

FIG. 3 is a flowchart illustrating some example embodiments of a method of operating a wafer map generating device of FIG. 1.

FIG. 4 is a diagram for describing a relationship between a plurality of target positions and a plurality of polarization matrices.

FIG. 5 is a diagram for describing some example embodiments of each of a plurality of polarization matrices of FIG. 4.

FIG. 6 is a diagram for describing some example embodiments of elements of each of a plurality of polarization matrices of FIG. 4.

FIG. 7 is a diagram for describing the process of performing dimension reduction on one or more elements of each of a plurality of polarization matrices of FIG. 4.

FIG. 8 is a diagram for describing the process of generating a plurality of reduction result data of FIG. 3.

FIGS. 9 and 10 are diagrams for describing some example embodiments of a wafer map of FIG. 3.

FIG. 11 is a diagram illustrating a result of comparing a wafer map generated by a wafer map generation device of FIG. 1 and a wafer map generated by using an electron microscope.

FIG. 12 is a flowchart illustrating a method of operating a wafer map generation device according to some example embodiments of the present disclosure.

FIG. 13 is a diagram for describing an operation of identifying a maximum value and a minimum value among values of a wafer map and an operation of generating additional information, which are described with reference to FIG. 12.

FIG. 14 is a block diagram illustrating a wafer map generation device according to some example embodiments.

FIG. 15 is a flowchart illustrating some example embodiments of a method of operating a wafer map generating device of FIG. 14.

FIG. 16 is a diagram for describing an operation of sequentially stacking a plurality of layers on a wafer substrate and an operation of generating a plurality of wafer maps, which are described with reference to FIG. 15.

FIG. 17 is a flowchart illustrating some example embodiments of a method of operating a wafer map generating device of FIG. 14.

FIG. 18 is a diagram for describing an operation of detecting abnormal process positions, which is described with reference to FIG. 17.

FIG. 19 is a flowchart illustrating some example embodiments of a method of operating a wafer map generating device of FIG. 14.

FIG. 20 is a diagram for describing an operation of detecting abnormal process steps, which is described with reference to FIG. 19.

FIG. 21 is a diagram for describing some example embodiments in which a wafer map generation device according to some example embodiments is used.

### DETAILED DESCRIPTION

Below, embodiments will be described in detail and clearly to such an extent that one skilled in the art easily carries out the present disclosure.

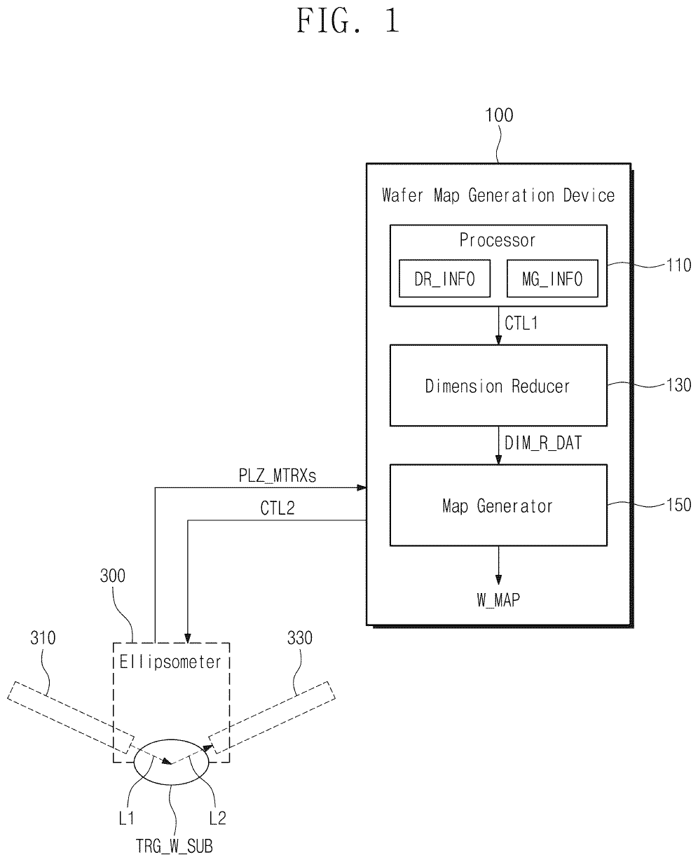

FIG. 1 is a block diagram illustrating a wafer map generation device according to some example embodiments.

Referring to FIG. 1, a wafer map generation device 100 may include a processor 110, a dimension reducer 130, and a map generator 150.

The processor 110 may control some or all of the operations of the dimension reducer 130 and the map generator 150 and may also control an operation of an external device. For example, the processor 110 may generate control signals CTL1 and CTL2 and may control the operations of the dimension reducer 130 and the map generator 150 inside the wafer map generation device 100 and the external device outside the wafer map generation device 100 based on the control signals CTL1 and CTL2.

The dimension reducer 130 may receive a plurality of polarization matrices PLZ_MTRXs associated with a plurality of target positions of a target wafer substrate TRG_W_SUB and may perform dimension reduction on one or more elements of each of the plurality of polarization matrices PLZ_MTRXs to generate a plurality of reduction result data DIM_R_DAT.

The map generator 150 may generate a wafer map W_MAP, e.g., a virtual wafer map W_MAP, associated with the target wafer substrate TRG_W_SUB based on the plurality of reduction result data DIM_R_DAT.

In some example embodiments, the target wafer substrate TRG_W_SUB may be or may include a semiconductor wafer substrate targeted for the generation of the wafer map W_MAP. The target wafer substrate TRG_W_SUB may be or may include a wafer substrate such as but not limited to a 200 mm-diameter substrate and/or a 300 mm-diameter substrate and/or a 450 mm-diameter substrate. Example embodiments are not limited thereto. The target wafer substrate TRG_W_SUB may be or may include a semiconductor substrate such as but not limited to a silicon substrate, a silicon-germanium (SiGe) substrate, a silicon-on-insulator (SOI) substrate, and/or a III-V substrate such as a gallium-nitride substrate. Example embodiments are not limited thereto.

In some example embodiments, the plurality of target positions may be or may include a plurality of locations determined in advance on the target wafer substrate TRG_W_SUB.

In some example embodiments, the plurality of polarization matrices PLZ_MTRXs may be received from an ellipsometer 300 being the external device of the wafer map generation device 100. The ellipsometer 300 may include a light emission unit 310 and a light detection unit 330. By using the light emission unit 310 and the light detection unit 330, the ellipsometer 300 may emit a plurality of first lights L1 to the plurality of target positions of the target wafer substrate TRG_W_SUB, respectively, and may obtain a plurality of second lights L2 respectively associated with the plurality of target positions. The ellipsometer 300 may generate the plurality of polarization matrices PLZ_MTRXs based on the plurality of first lights L1 and the plurality of second lights L2. For example, the plurality of first lights L1 may have a plurality of wavelength bands and a plurality of polarization states. For example, the plurality of first lights L1 may be respectively emitted to the plurality of target positions with different incidence angles. For example, the ellipsometer 300 may generate the plurality of polarization matrices PLZ_MTRXs by using stokes vectors associated with the plurality of first lights L1 and the plurality of second lights L2 or by using psi (Ψ) or delta (Δ) spectra associated with the plurality of first lights L1 and the plurality of second lights L2, but this is provided only as an example.

Signals, such as control signals CTL1, CTL2, reduction result data DIM_R_DAT, polarization matrices PLZ_MTRXs, and wafer map W_MAP may be sent to and/or received from various elements illustrated in FIG. 1 over a communication bus. The communication bus may be or may include a wired communication bus such as but not limited to an ethernet wiring and/or a metal routing line, and/or a wireless communication bus such as but not limited to Wi-Fi™ and/or Bluetooth® technology. Example embodiments are not limited thereto. The wafer map generation device 100 may be inside of the same building, e.g., inside of the same FAB, as that of the ellipsometer 300, or may be separated from the ellipsometer 300; example embodiments are not limited thereto.

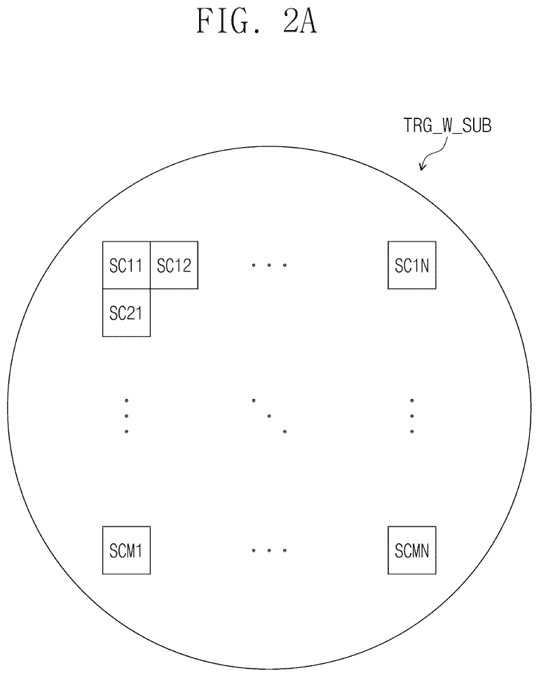

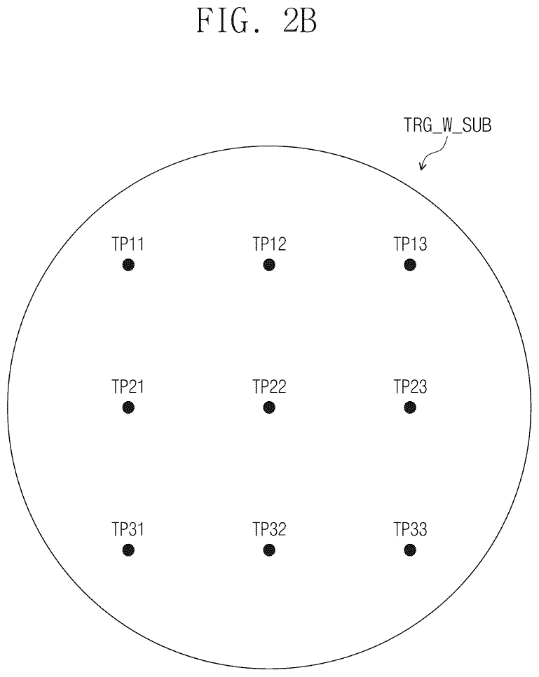

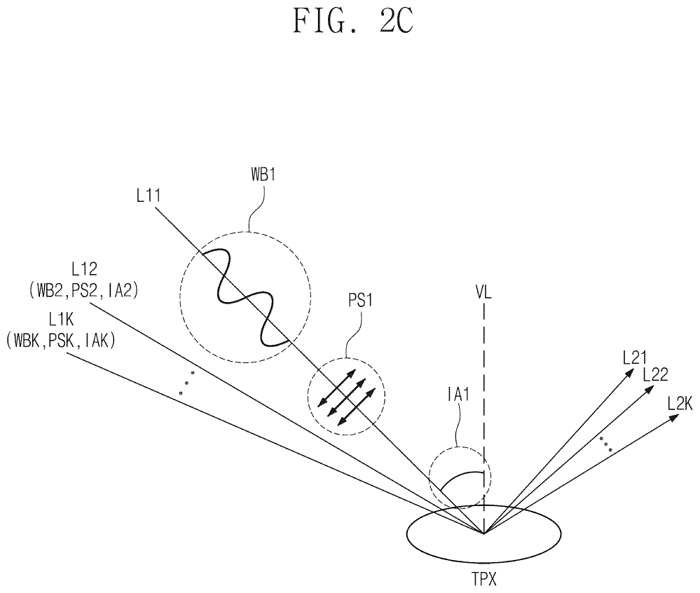

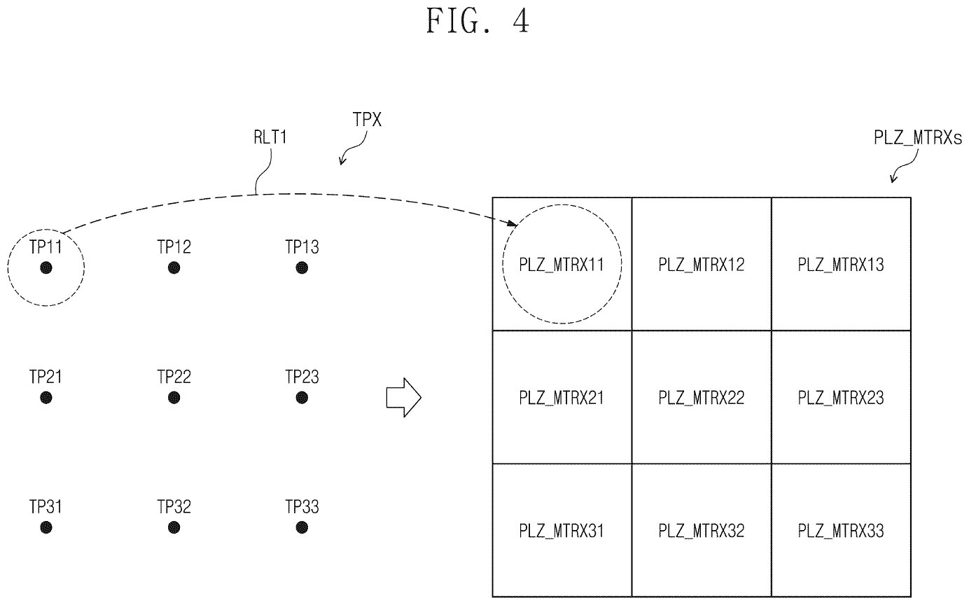

In some example embodiments, the plurality of polarization matrices PLZ_MTRXs and the plurality of reduction result data DIM_R_DAT may respectively correspond to the plurality of target positions. For example, one polarization matrix and one reduction result data may be generated for each target position. The plurality of target positions and the plurality of polarization matrices PLZ_MTRXs will be described in detail with reference to FIGS. 2B, 2C, and 4.

The dimension reducer 130 may generate the plurality of reduction result data DIM_R_DAT by performing the dimension reduction on one or more elements of each of the plurality of polarization matrices PLZ_MTRXs, and the map generator 150 may generate the wafer map W_MAP by mapping one or more components from each of the plurality of reduction result data DIM_R_DAT. For example, the wafer map W_MAP may visually show and/or predict a gradient such as a film thickness gradient, and/or the like of the upper surface of the target wafer substrate TRG_W_SUB.

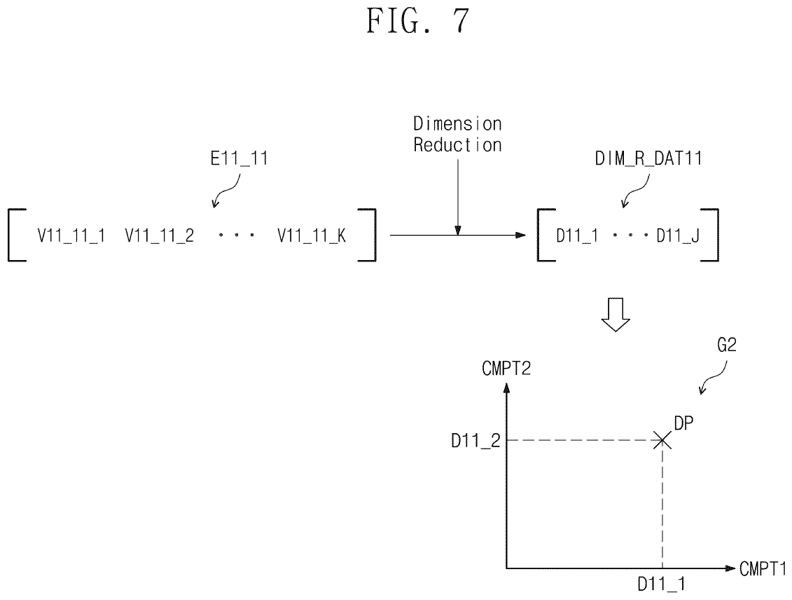

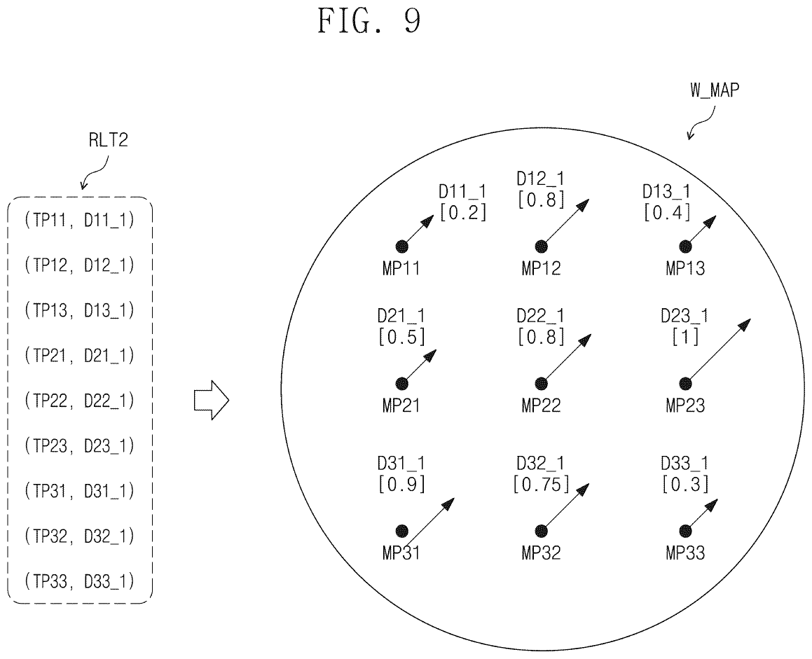

In some example embodiments, the dimension reducer 130 may perform the dimension reduction based on dimension reduction information DR_INFO, and the map generator 150 may perform the mapping based on map generation information MG_INFO. For example, the dimension reduction information DR_INFO may include various information associated with the dimension reduction, and the map generation information MG_INFO may include various information associated with the mapping. The dimension reduction information DR_INFO and the map generation information MG_INFO may be provided by the processor 110, and this is provided only as an example. While performing the dimension reduction and the mapping, the dimension reducer 130 and the map generator 150 may not use any electron microscope and may also not use any structure model for the spectrum result of the semiconductor wafer, e.g., of the uppermost films on the semiconductor wafer such as the target semiconductor wafer TRG_W_SUB. The dimension reduction will be described with reference to FIG. 7, and the mapping will be described with reference to FIGS. 9 and 10.

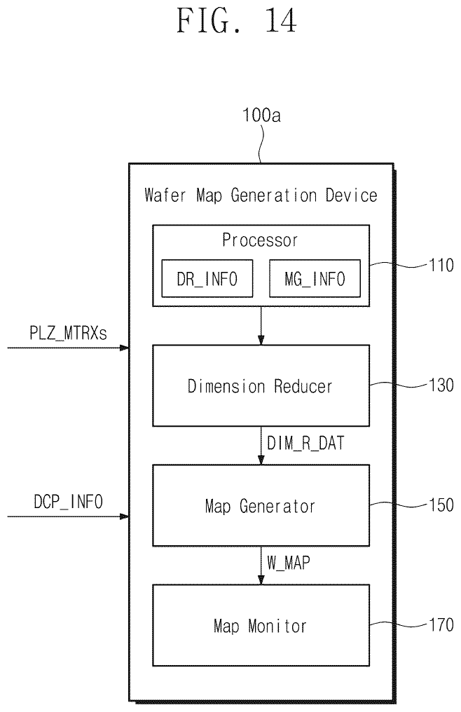

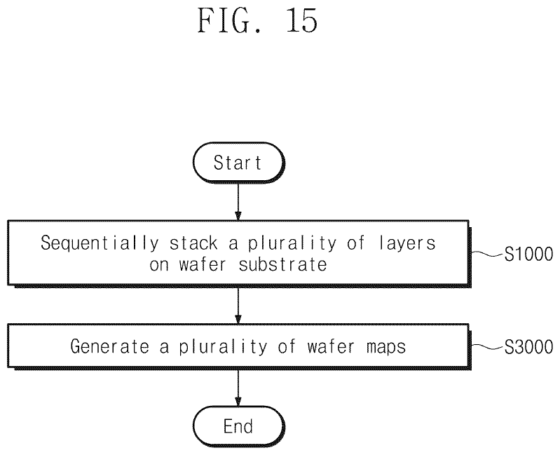

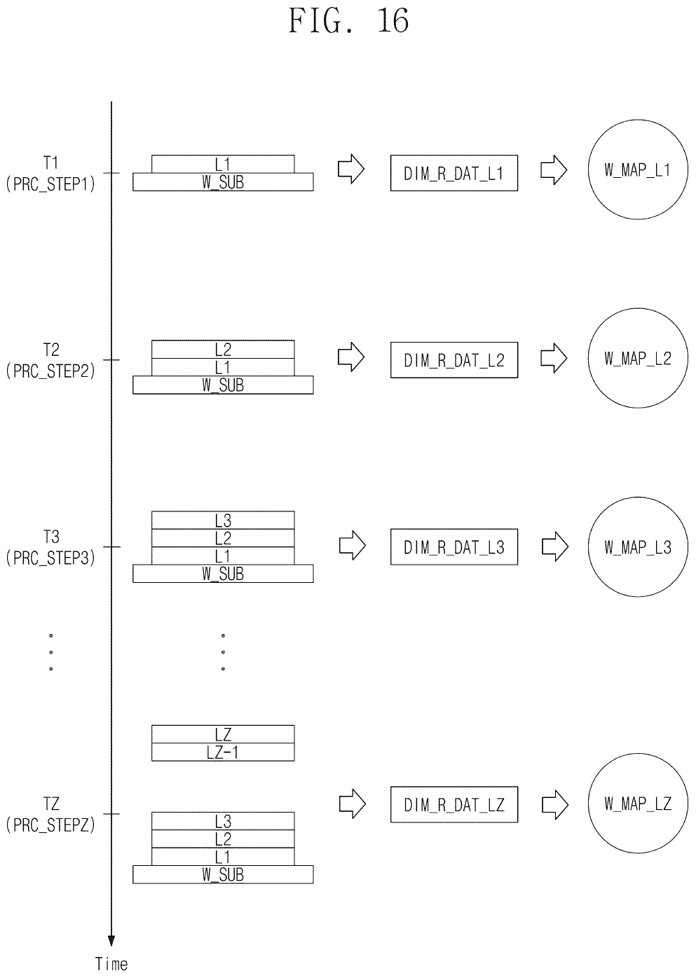

In some example embodiments, the wafer map generation device 100 may generate a plurality of wafer maps of a specific wafer substrate, e.g., having different uppermost films on the upper surface thereof, and may detect abnormal process locations and/or abnormal process steps based on the plurality of wafer maps. How the plurality of wafer maps are generated will be described with reference to FIGS. 15 and 16. How the abnormal process locations or the abnormal process steps are detected will be described with reference to FIGS. 17 to 20.

Through the above configuration, a wafer map generation device according to some example embodiments may generate a wafer map at high speed by only performing the dimension reduction and the mapping. The wafer map generation device may be usefully utilized even in an initial stage of development where the semiconductor fabrication process is frequently changed, for example as a process of record (POR) is changed so as to improve one or more of yield, reliability, and throughput, and thus, the development speed of a semiconductor product may be shortened and/or the yield and/or reliability thereof may be improved. Because the wafer map generation device does not use the electron microscope or the structure model for the spectrum result of the semiconductor wafer, the target wafer substrate may not be destroyed in the process of generating the wafer map, an issue of overfitting due to the small number of samples may be solved or may be improved upon, and the wafer map generation may be free from or improved upon an issue of model homeostasis, e.g., of unchanging model behavior.

FIG. 2A is a diagram for describing some example embodiments of a target wafer substrate of FIG. 1.

Referring to FIG. 2A, the target wafer substrate TRG_W_SUB may include a plurality of fully fabricated or at least partially fabricated semiconductor die or semiconductor chips SC11, SC12, . . . , SC1N and SC21, . . . , SCM1, . . . , SCMN (M and N being an integer of 3 or more). For example, the target wafer substrate TRG_W_SUB may be or may include a semiconductor wafer substrate which is targeted for the FAB process and/or the wafer test process in the semiconductor fabrication process, and is targeted for the generation of the wafer map W_MAP as described with reference to FIG. 1.

In some example embodiments, the plurality of semiconductor chips SC11 to SCMN may be disposed along rows and columns as illustrated in FIG. 2A, but the scope is not limited thereto. For example, each semiconductor chip SC11 to SCMN may have a rectangular, e.g., a square shape; example embodiments are not limited thereto. There may or may not be semiconductor chips on an edge of the target wafer substrate TRG_W_SUB; example embodiments are not limited thereto. There may or may not be a notch and/or a flat on the edge of the target wafer substrate TRG_W_SUB; example embodiments are not limited thereto.

FIG. 2B is a diagram for describing some example embodiments of a plurality of target positions of a target wafer substrate of FIG. 2A.

Referring to FIGS. 2A and 2B, a plurality of target positions TP11, TP12, TP13, TP21, TP22, TP23, TP31, TP32, TP33 may be set on the target wafer substrate TRG_W_SUB. The plurality of target positions TP11, . . . TP33 may be arranged on a grid, such as on corners of a square grid or rectangular grid, on the target wafer substrate TRG_W_SUB; example embodiments are not limited thereto.

In some example embodiments, as described with reference to FIG. 1, the ellipsometer 300 may emit the plurality of first lights L1 to the plurality of target positions TP11 to TP33, respectively, and may obtain the plurality of second lights L2 respectively associated with the plurality of target positions TP11 to TP33.

In some example embodiments, the number of target positions TP11 to TP33 may be less than the number of semiconductor chips SC11 to SCMN, but the scope of example embodiments is not limited thereto.

In some example embodiments, the plurality of target positions TP11 to TP33 may be disposed along rows and columns as illustrated in FIG. 2B, but the scope is not limited thereto. The gradient of the upper surface of the target wafer substrate TRG_W_SUB may be indicated by the wafer map W_MAP, and the number of target positions on the target wafer substrate TRG_W_SUB and/or the shape of arrangement of target positions on the target wafer substrate TRG_W_SUB may be variously changed or modified by the change in interest positions associated with the gradient of the upper surface.

FIG. 2C is a diagram for describing lights emitted to any one target position of FIG. 2B and lights reflected from the target position.

As described with reference to FIG. 1, the ellipsometer 300 may emit the plurality of first lights L1 to the plurality of target positions TP11 to TP33, respectively, and may obtain the plurality of second lights L2 respectively associated with the plurality of target positions TP11 to TP33. In FIG. 2C, a target position TPX may be one of the plurality of target positions TP11 to TP33 of FIG. 2B.

Referring to FIG. 2C, the plurality of first lights L1 may be emitted to the target position TPX. The plurality of first lights L1 may include lights L11, L12, . . . , L1K (K being an integer of 3 or more) which are different in each of (or at least one of) wavelength band, polarization state, and incidence angle. The incidence angle may be an angle which a virtual line VL being a direction perpendicular to the target position TRX and an incidence direction of each of the lights L11 to L1K form.

For example, the light L11 may have a wavelength band WB1, a polarization state PS1, and an incidence angle IA1, the light L12 may have a wavelength band WB2, a polarization state PS2, and an incidence angle IA2, and the light L1K may have a wavelength band WBK, a polarization state PSK, and an incidence angle IAK. However, the scope of example embodiments is not limited thereto. Some of the plurality of first lights L1 may have the same wavelength band and the same polarization state, and some of the plurality of first lights L1 may have the same incidence angle.

In some example embodiments, the lights L11 to L1K may be reflected at the target position TPX, and the plurality of second lights L2 may include reflected lights L21, L22, . . . , L2K.

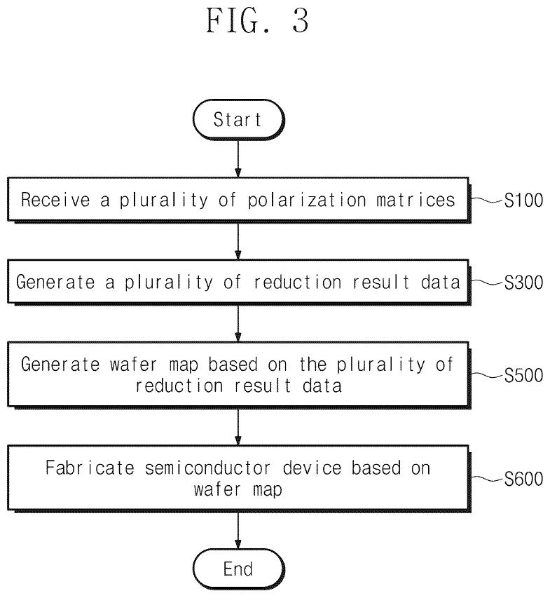

FIG. 3 is a flowchart illustrating some example embodiments of a method of operating a wafer map generating device of FIG. 1.

Referring to FIGS. 1 and 3, a plurality of polarization matrices associated with a plurality of target positions of a target wafer substrate may be received (S100).

In some example embodiments, operation S100 may be performed by the dimension reducer 130 of FIG. 1.

A plurality of reduction result data may be generated by performing the dimension reduction on one or more elements of each of the plurality of polarization matrices (S300).

In some example embodiments, operation S300 may be performed by the dimension reducer 130 of FIG. 1.

A wafer map associated with the target wafer substrate may be generated based on the plurality of reduction result data (S500).

In some example embodiments, operation S500 may be performed by the map generator 150 of FIG. 1.

A device such as a semiconductor device may be fabricated based on the wafer map associated with the target wafer substrate (S600). In some example embodiments, operation S600 may be performed or at least partially performed by the wafer map generation device 100 of FIG. 1; example embodiments are not limited thereto.

FIG. 4 is a diagram for describing a relationship between a plurality of target positions and a plurality of polarization matrices.

Referring to FIGS. 2B and 4, the plurality of polarization matrices PLZ_MTRXs may include polarization matrices PLZ_MTRX11, PLZ_MTRX12, PLZ_MTRX13, PLZ_MTRX21, PLZ_MTRX22, PLZ_MTRX23, PLZ_MTRX31, PLZ_MTRX32, and PLZ_MTRX33, and the polarization matrices PLZ_MTRX11 to PLZ_MTRX33 may respectively correspond to, e.g., correspond one-to-one to, the plurality of target positions TP11 to TP33.

For example, the polarization matrix PLZ_MTRX11 may correspond to the target position TP11 (RLT1), the polarization matrix PLZ_MTRX12 may correspond to the target position TP12, and the polarization matrix PLZ_MTRX13 may correspond to the target position TP13 (RLT1). As in the above description, the remaining polarization matrices PLZ_MTRX21 to PLZ_MTRX33 may respectively correspond to target positions in the same method as the polarization matrices PLZ_MTRX11, PLZ_MTRX12, and PLZ_MTRX13.

For example, the polarization matrix PLZ_MTRX11 may be associated with the target position TP11 (RLT1) and may be generated based on lights emitted to the target position TP11 and lights reflected from the target position TP11. The polarization matrix PLZ_MTRX12 may be associated with the target position TP12 and may be generated based on lights emitted to the target position TP12 and lights reflected from the target position TP12. The polarization matrix PLZ_MTRX13 may be associated with the target position TP13 and may be generated based on lights emitted to the target position TP13 and lights reflected from the target position TP13. As in the above description, the remaining polarization matrices PLZ_MTRX21 to PLZ_MTRX33 may respectively associated with target positions in the same method as the polarization matrices PLZ_MTRX11, PLZ_MTRX12, and PLZ_MTRX13.

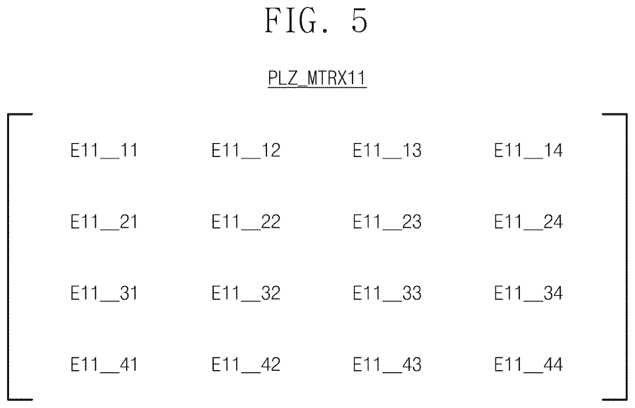

FIG. 5 is a diagram for describing some example embodiments of each of a plurality of polarization matrices of FIG. 4.

One PLZ_MTRX11 of the plurality of polarization matrices PLZ_MTRX11 to PLZ_MTRX33 of FIG. 4 is illustrated in FIG. 5 as an example. The remaining polarization matrices PLZ_MTRX12 to PLZ_MTRX33 may also have the same shape as (e.g., the same number of rows as and/or the number of columns as) the polarization matrix PLZ_MTRX11. The plurality of polarization matrices PLZ_MTRX11 to PLZ_MTRX33 may be generated by the external device (e.g., the ellipsometer 300 of FIG. 1) and may be input to the wafer map generation device 100 (or the dimension reducer 130) of FIG. 1.

Referring to FIG. 5, the polarization matrix PLZ_MTRX11 may include a plurality of elements E11_11, E11_12, E11_13, E11_14, E11_21, E11_22, E11_23, E11_24, E11_31, E11_32, E11_33, E11_34, E11_41, E11_42, E11_43, and E11_44. For example, in the element E11_12, “11” may indicate that a relevant element is associated with the polarization matrix PLZ_MTRX11, and “12” may indicate a position of a relevant element in the polarization matrix PLZ_MTRX11, that is, that a relevant element is positioned at the first row and second column. For example, the polarization matrix PLZ_MTRX11 may be in the shape of a 4×4 matrix, but this is provided only as an example. The number of rows and/or the number of columns of the polarization matrix PLZ_MTRX11 may be the same as, greater than, or less than the number of rows and/or the number of columns of the target positions TP.

In some example embodiments, the polarization matrix PLZ_MTRX11 may be generated based on obtaining a plurality of second lights from a first target position of a target wafer substrate after emitting a plurality of first lights with a plurality of wavelength bands and a plurality of polarization states to the first target position.

In some example embodiments, the polarization matrix PLZ_MTRX11 may indicate polarization states of the plurality of second lights reflected from the first target position.

In some example embodiments, the polarization matrix PLZ_MTRX11 may include one of or both of a Mueller matrix and a Jones matrix, but the scope of example embodiments is not limited thereto.

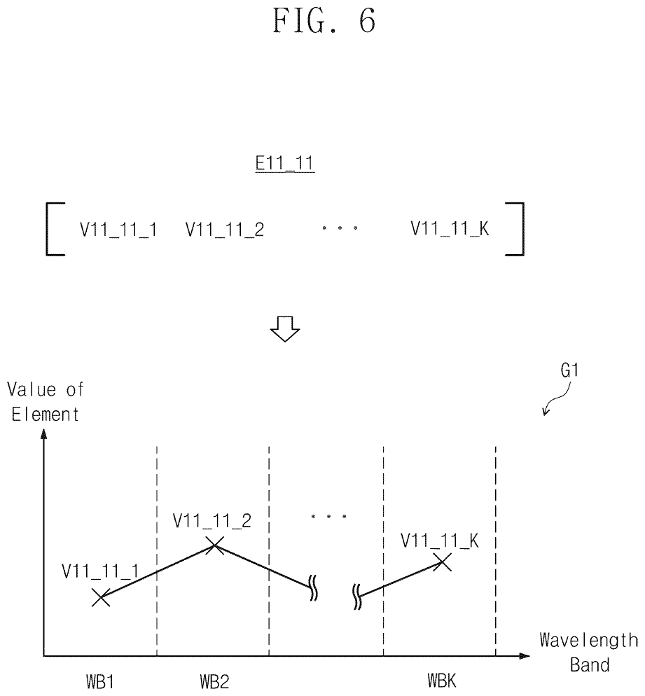

FIG. 6 is a diagram for describing some example embodiments of elements of each of a plurality of polarization matrices of FIG. 4.

Referring to FIGS. 4 to 6, the element E11_11 of the polarization matrix PLZ_MTRX11 may have dimension 1×K (K being an integer of 2 or more). For example, the element E11_11 may include K values V11_11_1, V11_11_2, . . . , V11_11_K, and the “K” may indicate the number of different wavelength bands (e.g., WB1, WB2, . . . , WBK described with reference to FIG. 2C) with which the plurality of first lights L1 have. For example, for convenience of description, the element E11_11 may be illustrated by a plurality of dots and/or a plurality of line segments on a graph G1 in which the horizontal axis represents a wavelength band and the vertical axis represents a value of an element.

In some example embodiments, the remaining elements E11_12 to E11_44 of the polarization matrix PLZ_MTRX11 may also have the same dimensions as the element E11_11 and may be expressed in the same manner as the element E11_11.

FIG. 7 is a diagram for describing the process of performing dimension reduction on one or more elements of each of a plurality of polarization matrices of FIG. 4.

In FIG. 7, the element E11_11 of the polarization matrix PLZ_MTRX11 and the reduction result data DIM_R_DAT obtained through the dimension reduction of the element E11_11 are illustrated. The dimension reduction may be performed by the dimension reducer 130 of FIG. 1 based on the dimension reduction information DR_INFO.

Referring to FIGS. 6 and 7, the element E11_11 of the polarization matrix PLZ_MTRX11 may have dimension 1×K (K being an integer of 2 or more), and the reduction result data DIM_R_DAT may have dimension 1×J (J being an integer of 2 or more).

For example, the element E11_11 may include the K values V11_11_1, V11_11_2, . . . , V11_11_K, and the reduction result data DIM_R_DAT may include J values D11_1, . . . , D11_J.

For example, the dimensions of the reduction result data DIM_R_DAT may be equal to or less than the dimensions of the element E11_11 of the polarization matrix PLZ_MTRX11. For example, the “J” may be equal to or less than the “K”.

For example, for convenience of description, the reduction result data DIM_R_DAT as illustrated in FIG. 7 may be indicated by a dot on a graph G2 in which the horizontal axis represents a first component CMPT1 and the vertical axis represents a second component CMPT2.

In some example embodiments, an algorithm for the dimension reduction may include one or more of a principle component analysis (PCA) algorithm, a t-distributed stochastic neighbor embedding (t-SNE) algorithm, and a uniform manifold approximation and projection (UMAP) algorithm, but the scope of example embodiments is not limited thereto. In particular, a statistical dimension and/or a correlation of each of the K values V11_11_1, V11_11_2, . . . , V11_11_K may be determined with a PCA algorithm, and certain principal components may be assessed as being above or below a threshold. From the PCA algorithm, these principal components may be filtered, and the J values D11_1, . . . , D11_J may be generated. In some example embodiments, the dimension reduction algorithm may be the same for each of the polarization matrices PLZ_MTRX; however, example embodiments are not limited thereto.

In some example embodiments, reduction result data obtained through the dimension reduction of the remaining elements E11_12 to E11_44 of the polarization matrix PLZ_MTRX11 may also have the same dimensions as the reduction result data DIM_R_DAT, and may be expressed in the same manner as the reduction result data DIM_R_DAT.

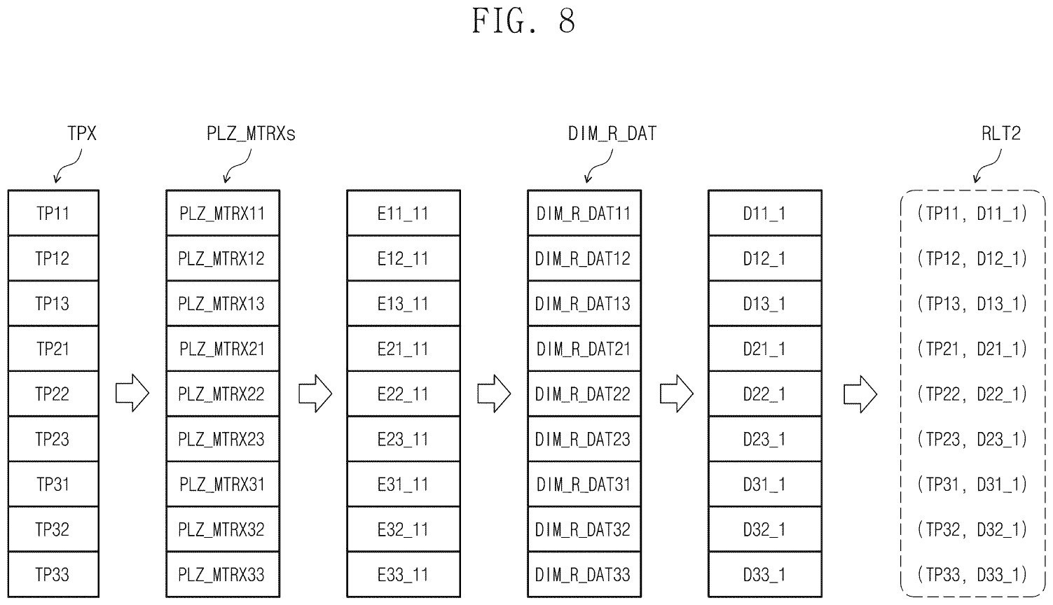

FIG. 8 is a diagram for describing the process of generating a plurality of reduction result data of FIG. 3.

In association with all the target positions TP11 to TP33, the process of generating reduction result data of one target position, which is described with reference to FIGS. 4 to 7, is illustrated in FIG. 8.

In some example embodiments, the ellipsometer 300 of FIG. 1 may generate all the polarization matrices PLZ_MTRXs (e.g., PLZ_MTRX11 to PLZ_MTRX33) respectively corresponding to the plurality of target positions TPX (e.g., TP11 to TP33).

In some example embodiments, the dimension reducer 130 of FIG. 1 may select elements at one or more rows and one or more columns from each of the plurality of polarization matrices PLZ_MTRXs based on the dimension reduction information DR_INFO and may select at least one algorithm for the dimension reduction. The dimension reducer 130 may generate the plurality of reduction result data DIM_R_DAT (e.g., DIM_R_DAT11 to DIM_R_DAT33) by applying the algorithm for the dimension reduction to the selected element.

In some example embodiments, the map generator 150 of FIG. 1 may select one or more components (e.g., D11_1 to D33_1) from each of the plurality of reduction result data DIM_R_DAT based on the map generation information MG_INFO.

In some example embodiments, the map generator 150 may generate a wafer map such as a virtual wafer map by mapping the one or more components to a corresponding mapping position of the wafer map. For example, the map generator 150 may identify a relationship RLT2 between one or more components of each of the plurality of target positions TP11 to TP33 and the plurality of reduction result data DIM_R_DAT and may generate a wafer map by mapping the one or more components to mapping positions of the wafer map corresponding to the plurality of target positions TP11 to TP33.

FIGS. 9 and 10 are diagrams for describing some example embodiments of a wafer map of FIG. 3.

The relationship RLT2 between one or more components of each of the plurality of target positions TP11 to TP33 and the plurality of reduction result data DIM_R_DAT and the wafer map W_MAP are illustrated in FIG. 9, and the wafer map W_MAP and scaled wafer map SCLD_W_MAP are illustrated in FIG. 10. The generation of the wafer map W_MAP and/or the generation of the scaled wafer map SCLD_W_MAP may be performed by the map generator 150 of FIG. 1. In each of the wafer map W_MAP and the scaled wafer map SCLD_W_MAP, mapping positions MP11, MP12, MP13, MP21, MP22, MP23, MP31, MP32, and MP33 may respectively correspond to the plurality of target positions TP11 to TP33.

Referring to FIG. 9, one component of each of the plurality of reduction result data DIM_R_DAT (e.g., first components D11_1 to D33_1 of the plurality of reduction result data DIM_R_DAT) may be selected by the map generator 150, and the selected components may be mapped to corresponding mapping positions of the wafer map W_MAP as it is. For example, a value of the component D11_1 may be 0.2, and 0.2 may be mapped to the mapping position MP11 as it is. For example, a value of the component D12_1 may be 0.8, and 0.8 may be mapped to the mapping position MP12 as it is. For example, a value of the component D13_1 may be 0.4, and 0.4 may be mapped to the mapping position MP13 as it is. As in the above description, the components D21_1 to D33_1 may also be mapped to the mapping positions MP21 to MP33 as it is, in the same method as the components D11_1, D12_1, and D13_1.

In some example embodiments, when two or more components of each of the plurality of reduction result data DIM_R_DAT (e.g., the first components D11_1 to D33_1 and the second components D11_2 to D33_2 of the plurality of reduction result data DIM_R_DAT) are selected by the map generator 150, a value of performing an arithmetic operation on the first component and the second component corresponding to each other may be mapped to the mapping position. For example, a value of performing the arithmetic operation on paired components selected from the same reduction result data may be mapped to the mapping position.

In some example embodiments, values may be filled in empty regions of the wafer map W_MAP by performing the interpolation or extrapolation on the remaining regions of the wafer map W_MAP other than the mapping positions MP11 to MP33.

Referring to FIG. 10, the components D11_1 to D33_1 mapped to the mapping positions MP11 to MP33 of the wafer map W_MAP may be scaled to be mapped to corresponding mapping positions of the scaled wafer map SCLD_W_MAP.

For example, when a scaling factor is 20, a value of the component D11_1 may be 0.2, and a value of the scaled component S_D11_1 may be 4. As in the component D11_1, the remaining components D12_1 to D33_1 may be scaled.

In some example embodiments, the map generator 150 of FIG. 1 may identify the scaling factor for the scaling based on the map generation information MG_INFO.

In some example embodiments, as illustrated in FIG. 9, after the wafer map W_MAP is generated, when a fine measurement value for a specific position of the target wafer substrate is provided by a separate fine device, the scaling factor may be determined, and the scaled wafer map SCLD_W_MAP may be generated by performing the scaling as illustrated in FIG. 10.

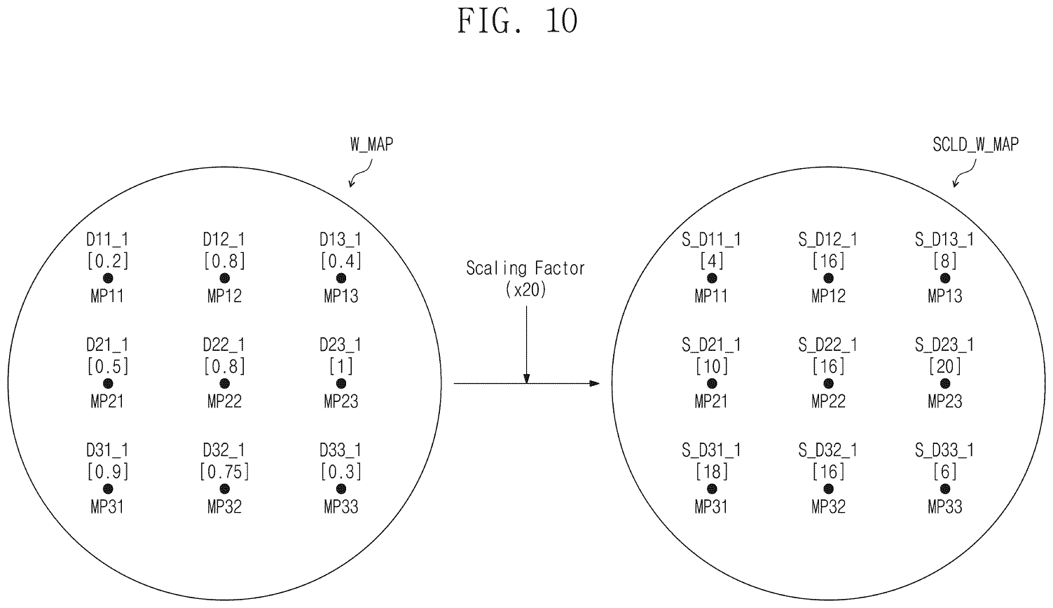

FIG. 11 is a diagram illustrating a result of comparing a wafer map generated by a wafer map generation device of FIG. 1 and a wafer map generated by using an electron microscope.

CASE1, CASE2, and CASE3 are illustrated in FIG. 11.

In CASE1, CASE2, and CASE3, the reduction result data DIM_R_DAT may include a result of performing the dimension reduction on the plurality of polarization matrices PLZ_MTRXs by using the PCA, and may be indicated by a graph (e.g., G2 of FIG. 7). For example, the horizontal axis represents a first principle component PCA1 being a first component (e.g., CMPT1 of FIG. 7) of the PCA, and the vertical axis represents a second principle component PCA2 of the PCA being a second component (e.g., CMPT2 of FIG. 7).

In CASE1, CASE2, and CASE3, the wafer map W_MAP may be expressed according to the method described with reference to FIGS. 4 to 9 and may be compared with a wafer map W_MAP(SEM) generated by using a scanning microscope (e.g., a scanning electron microscope (SEM)). The similarity between the wafer map W_MAP and the wafer map W_MAP(SEM) may be expressed by using a determination or correlation coefficient (R²) (R-squared), and it may be understood from a simulation result that the determination coefficient is 0.9 or more in CASE1, CASE2, and CASE3, for example, that the quality of the wafer map generated by the wafer map generation device according to embodiments is the same level as the wafer map W_MAP(SEM) generated by using the scanning microscope.

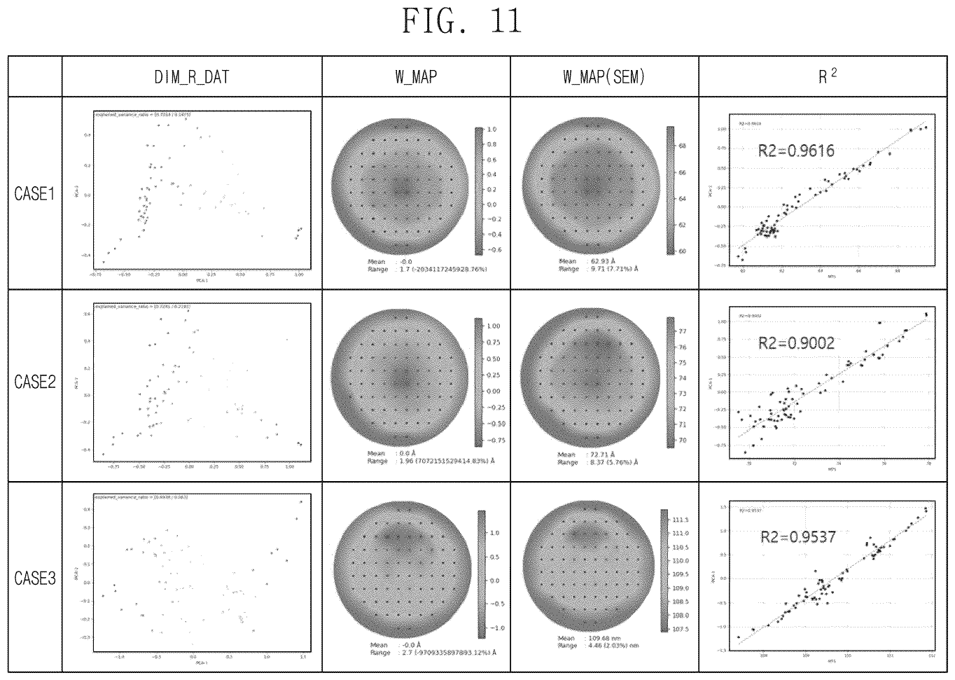

FIG. 12 is a flowchart illustrating a method of operating a wafer map generation device according to some example embodiments.

Compared to the flowchart of FIG. 3, the flowchart of FIG. 12 may further include operation S700 and operation S900.

Referring to FIGS. 1, 3, and 12, a plurality of polarization matrices associated with a plurality of target positions of a target wafer substrate may be received (S100).

In some example embodiments, operation S100 may be performed by the dimension reducer 130 of FIG. 1.

A plurality of reduction result data may be generated by reducing the dimensions of one or more elements of each of the plurality of polarization matrices (S300).

In some example embodiments, operation S300 may be performed by the dimension reducer 130 of FIG. 1.

A wafer map associated with the target wafer substrate may be generated based on the plurality of reduction result data (S500).

In some example embodiments, operation S500 may be performed by the map generator 150 of FIG. 1.

A value associated with a maximum value and a value associated with a minimum value from among values of the wafer map may be identified (S700).

Additional information for fine measurement of the target wafer substrate may be generated based on the maximum value and the minimum value (S900).

In some example embodiments, operation S700 and operation S900 may be performed by the map generator 150 of FIG. 1.

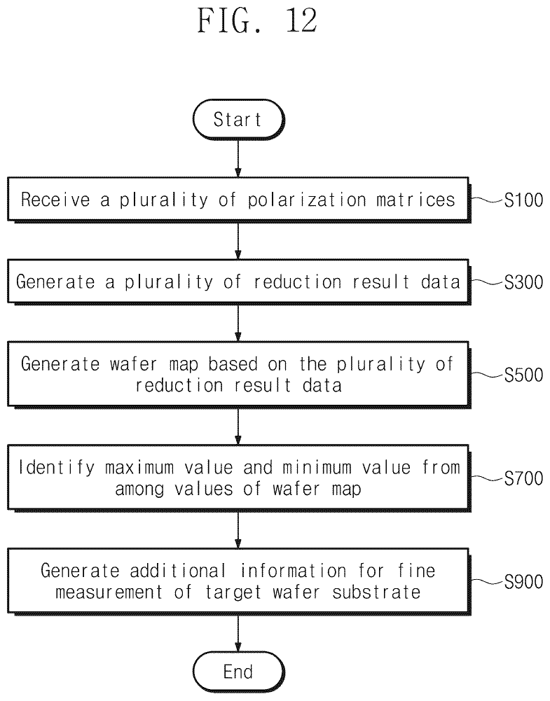

FIG. 13 is a diagram for describing an operation of identifying a value associated with a maximum value and a value associated with a minimum value from among values of a wafer map and an operation of generating additional information, which are described with reference to FIG. 12.

Referring to FIGS. 12 and 13, a large, e.g., a maximum value, and a small, e.g., a minimum value, from among values of the wafer map W_MAP may be identified. For example, the wafer map W_MAP illustrated in FIG. 13 may be the same as the wafer map W_MAP illustrated in FIG. 9 and may have values D11_1 to D33_1 at the mapping positions MP11 to MP33.

In some example embodiments, the map generator 150 may identify a maximum value (e.g., a value [1] of D23_1) and a minimum value (e.g., a value [0.2] of D11_1) in the wafer map W_MAP.

In some example embodiments, the map generator 150 may generate a line on a test wafer substrate TEST_W_SUB, which corresponds to a line connecting mapping positions with the maximum value and the minimum value, as the additional information in operation S900 of FIG. 12. For example, the line on the test wafer substrate TEST_W_SUB may be expressed by using test positions TSTP11, TSTP12, TSTP13, TSTP21, TSTP22, TSTP23, TSTP31, TSTP32, and TSTP33 of the test wafer substrate TEST_W_SUB, which correspond to the mapping positions MP11 to MP33 of the wafer map W_MAP. For example, in the wafer map W_MAP, when the maximum value is the value [1] of D23_1 and the minimum value is the value [0.2] of D11_1, as illustrated in FIG. 13, the additional information may indicate a line connecting TSTP11 and TSTP23.

In some example embodiments, in a case of observing the cross section after cutting the test wafer substrate TEST_W_SUB for the fine measurement of the test wafer substrate TEST_W_SUB, the line according to the additional information may correspond to the cutting line of the test wafer substrate TEST_W_SUB.

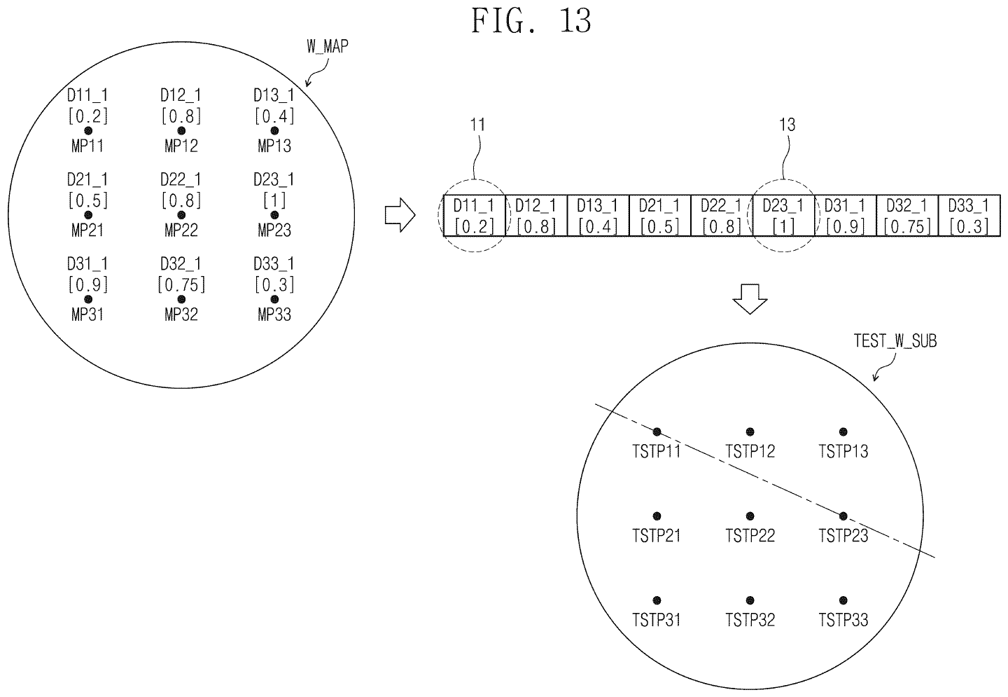

FIG. 14 is a block diagram illustrating a wafer map generation device according to some example embodiments.

Compared to the wafer map generation device 100 of FIG. 1, a wafer map generation device 100a of FIG. 14 may further include a map monitor 170 and may further receive defective chip position information DCP_INFO. Thus, additional description will be omitted to avoid redundancy.

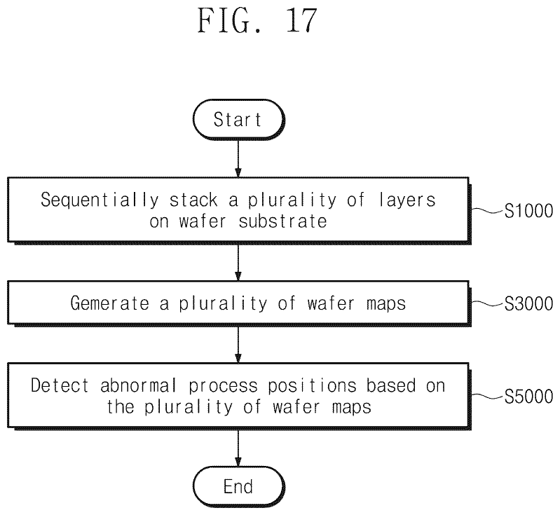

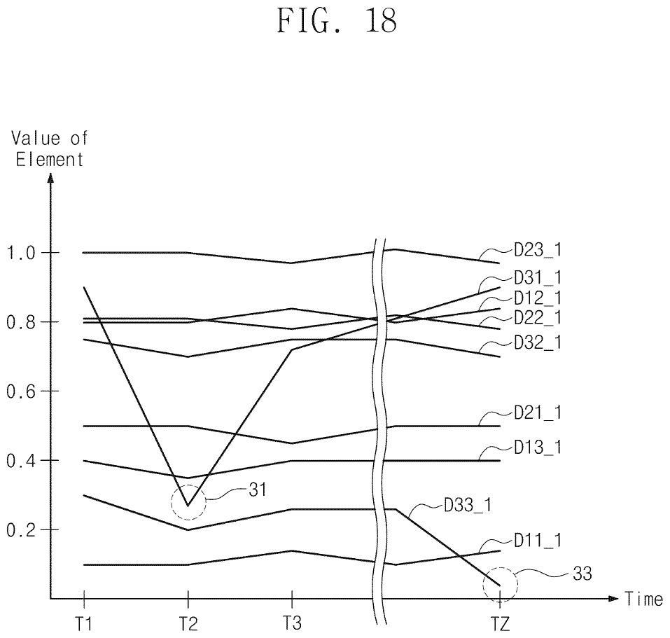

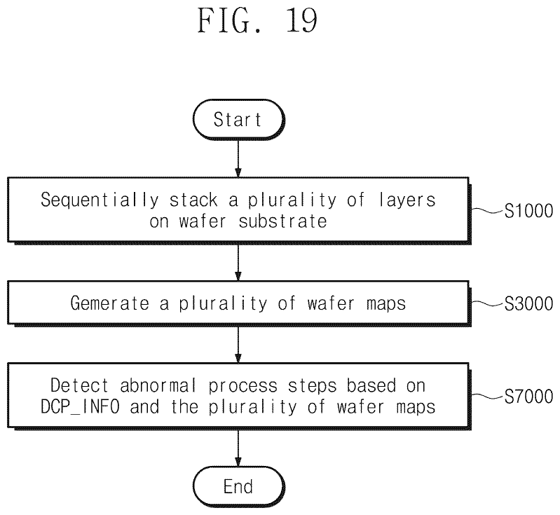

In some example embodiments, the map monitor 170 may detect abnormal process positions based on a plurality of wafer maps and may detect abnormal process steps based on the defective chip position information DCP_INFO and the plurality of wafer maps. The detection of the abnormal process positions will be described with reference to FIGS. 17 and 18, and the detection of the abnormal process steps will be described with reference to FIGS. 19 and 20.

FIG. 15 is a flowchart illustrating some example embodiments of a method of operating a wafer map generating device of FIG. 14.

Referring to FIG. 15, a plurality of layers, e.g., a plurality of films, may be sequentially stacked on a wafer substrate (S1000).

A plurality of wafer maps, e.g., a plurality of virtual wafer maps, corresponding to a plurality of target wafer substrates may be generated by setting the wafer substrate as a target wafer substrate whenever one layer is completely stacked on the wafer substrate (S3000).

In some example embodiments, operation S3000 may be performed by the wafer map generation device 100a of FIG. 14.

In some example embodiments, each of the plurality of wafer maps may be generated based on the method described with reference to FIG. 3 or 10. For example, in operation S3000, a plurality of polarization matrices associated with a plurality of target positions of each of the plurality of target wafer substrates may be received. A plurality of reduction result data may be generated through the dimension reduction of one or more elements of each of the plurality of polarization matrices. The plurality of wafer maps respectively associated with the plurality of target wafer substrates may be generated based on the plurality of reduction result data.

FIG. 16 is a diagram for describing an operation of sequentially stacking a plurality of layers on a wafer substrate and an operation of generating a plurality of wafer maps, which are described with reference to FIG. 15.

In FIG. 16, as time points T1, T2, T3, . . . , TZ (Z being an integer of 4 or more) sequentially pass, a plurality of layers L1, L2, L3, . . . , LZ may be sequentially stacked on a wafer substrate W_SUB.

In some example embodiments, the time points T1 to TZ may respectively correspond to semiconductor fabrication process operations PRC_STEP1, PRC_STEP2, PRC_STEP3, . . . , PRC_STEPZ. For example, at the semiconductor fabrication process operation PRC_STEP1, the layer L1 may be stacked on the wafer substrate W_SUB; at the semiconductor fabrication process operations PRC_STEP2, the layer L2 may be stacked on the layer L1. At the semiconductor fabrication process step PRC_STEP3, the layer L3 may be stacked on the layer L2; at the semiconductor fabrication process step PRC_STEPZ, the layer LZ may be stacked on the layer LZ-1.

In some example embodiments, the wafer substrate W_SUB of the processing point or time point T1 may be set as a target wafer substrate, and reduction result data DIM_R_DAT1 targeted for the target wafer substrate may be generated. The wafer substrate W_SUB of the processing point or time point T2 may be set as a target wafer substrate, and reduction result data DIM_R_DAT2 targeted for the target wafer substrate may be generated. The wafer substrate W_SUB of the time point T3 may be set as a target wafer substrate, and reduction result data DIM_R_DAT3 targeted for the target wafer substrate may be generated. The wafer substrate W_SUB of the time point TZ may be set as a target wafer substrate, and reduction result data DIM_R_DATZ targeted for the target wafer substrate may be generated.

In some example embodiments, a virtual wafer map such as a wafer map W_MAP_L1 corresponding to the wafer substrate W_SUB of the time point T1 may be generated based on the reduction result data DIM_R_DAT1. A wafer map W_MAP_L2 corresponding to the wafer substrate W_SUB of the time point T2 may be generated based on the reduction result data DIM_R_DAT2. A wafer map W_MAP_L3 corresponding to the wafer substrate W_SUB of the time point T3 may be generated based on the reduction result data DIM_R_DAT3. A wafer map W_MAP_LZ corresponding to the wafer substrate W_SUB of the time point TZ may be generated based on the reduction result data DIM_R_DATZ.

FIG. 17 is a flowchart illustrating some example embodiments of a method of operating a wafer map generating device of FIG. 14.

Compared to the flowchart of FIG. 15, the flowchart of FIG. 17 may further include operation S5000.

Referring to FIGS. 15 and 17, a plurality of layers may be sequentially stacked on a wafer substrate (S1000).

A plurality of wafer maps corresponding to a plurality of target wafer substrates may be generated by setting the wafer substrate as a target wafer substrate whenever one layer is completely stacked on the wafer substrate (S3000).

In some example embodiments, operation S3000 may be performed by the wafer map generation device 100a (or the map generator 150) of FIG. 14.

Abnormal process positions may be detected based on the plurality of wafer maps (S5000).

In some example embodiments, operation S5000 may be performed by the wafer map generation device 100a (or the map monitor 170) of FIG. 14.

FIG. 18 is a diagram for describing an operation of detecting abnormal process positions, which is described with reference to FIG. 17.

Referring to FIGS. 14, 17, and 18, the map monitor 170 may monitor values corresponding to specific positions from among values of the plurality of wafer maps at the time points T1, T2, T3, . . . , TZ.

In some example embodiments, the map monitor 170 may monitor values (e.g., D11_1 to D33_1) of wafer maps, which correspond to the mapping positions MP11 to MP33 as illustrated in FIG. 9 or 13.

In some example embodiments, as the processing points or time points T1 to TZ pass, as illustrated in FIG. 18, the values of the wafer maps may change. The map monitor 170 may determine that the probability that an abnormal process is caused at time points (e.g., T2 and TZ) corresponding to the case where a value of a wafer map sharply changes as much as a given level or more like a value (e.g., 31) of D31_1 or a value (e.g., 33) of D33_1 is high and may detect mapping positions corresponding to D31_1 and D33_1 as the abnormal process positions in operation S5000.

FIG. 19 is a flowchart illustrating some example embodiments of a method of operating a wafer map generating device of FIG. 14.

Compared to the flowchart of FIG. 15, the flowchart of FIG. 19 may further include operation S7000.

Referring to FIGS. 15 and 19, a plurality of layers, e.g., a plurality of physical layers, may be sequentially stacked on a wafer substrate (S1000).

A plurality of wafer maps, e.g., a plurality of virtual wafer maps, corresponding to a plurality of target wafer substrates may be generated by setting the wafer substrate as a target wafer substrate whenever one layer is completely stacked on the wafer substrate (S3000).

In some example embodiments, operation S3000 may be performed by the wafer map generation device 100a (or the map generator 150) of FIG. 14.

Abnormal process steps may be detected based on the defective chip position information DCP_INFO (refer to FIG. 14) and the plurality of wafer maps (S7000).

FIG. 20 is a diagram for describing an operation of detecting abnormal process steps, which is described with reference to FIG. 19.

Referring to FIGS. 14, 19, and 20, the map monitor 170 may identify positions (e.g., 51 and 53) of a defective wafer substrate DEF_W_SUB, at which defective chips occur, based on the defective chip position information DCP_INFO.

The map monitor 170 may detect time points corresponding to the case where a value of a wafer map sharply changes as much as a given level or more, by monitoring values of the plurality of wafer maps, which correspond to the positions where the defective chips occur, to be similar to operation S5000 described with reference to FIGS. 17 and 18. The map monitor 170 may detect fabrication process steps or fabrication process operations corresponding to the detected time points as the abnormal process steps or abnormal process operations. In some example embodiments, upon detection of an abnormal process operation, the process operation may be modified so as to affect, e.g., to improve, the process operation and/or decrease the likelihood that the process operation is abnormal.

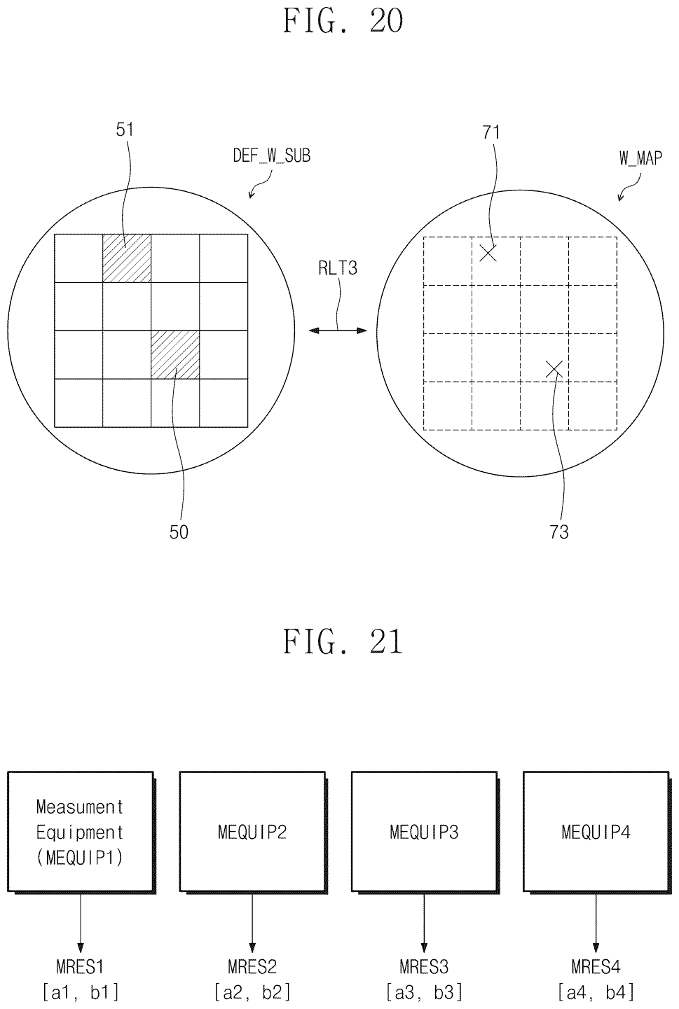

FIG. 21 is a diagram for describing some example embodiments in which a wafer map generation device according to some example embodiments is used.

Various processing equipment and/or measurement equipment MEQUIP1, MEQUIP2, MEQUIP3, and MEQUIP4 for measuring a characteristic of a wafer substrate, for example, the gradient or the like of the wafer substrate are illustrated in FIG. 21.

For example, even though the measurement equipment MEQUIP1 to MEQUIP4 measures the same wafer substrate, results of different ranges may be output due to settings of manufacturers of the measurement equipment MEQUIP1 to MEQUIP4. For example, the measurement equipment MEQUIP1 may output a result MRES1 between a minimum value a1 and a maximum value b1, and the measurement equipment MEQUIP2 may output a result MRES2 between a minimum value a2 and a maximum value b2. The measurement equipment MEQUIP3 may output a result MRES3 between a minimum value a3 and a maximum value b3, and the measurement equipment MEQUIP4 may output a result MRES4 between a minimum value a4 and a maximum value b4.

In some example embodiments, a wafer map (e.g., W_MAP of FIG. 9) generated by some example embodiments may provide reference values for comparison between the results MRES1, MRES2, MRES3, and MRES4 of the various measurement equipment MEQUIP1 to MEQUIP4.

As described above, a wafer map generation device according to some example embodiments may generate a wafer map at high speed by only performing a dimension reduction and a mapping. The wafer map generation device may be usefully utilized even in an initial stage of development where a semiconductor fabrication process is frequently changed, and thus, the speed of development of a semiconductor product may be shortened. Alternatively or additionally, because the wafer map generation device does not use an electron microscope or a structure model for a spectrum result of the semiconductor wafer, the target wafer substrate may not be destructed in the process of generating the wafer map, the issue of overfitting due to the small number of samples may be solved or improved upon, and it may be free from or improved over the issue of model homeostasis.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

In some example embodiments, at least some functions described as being performed by one element may alternatively or additionally be performed by another element; example embodiments are not limited thereto. For example, a single processor may perform each of the operations described with reference to the wafer map generation device 100; example embodiments are not limited thereto. The single processor may perform operations upon reading computer-readable instructions. The computer-readable instructions may be stored in a non-transitory computer-readable medium. Example embodiments are not limited thereto.

While some example embodiments have been described with reference to some example embodiments thereof, it will be apparent to those of ordinary skill in the art that various changes and modifications may be made thereto without departing from the spirit and scope as set forth in the following claims. Additionally, example embodiments are not necessarily mutually exclusive. For example, some example embodiments may include one or more features described with reference to one or more figures, and may also include one or more other features described with reference to one or more other figures.

What is claimed is:

1. A wafer map generation device comprising:
a dimension reducer configured to receive a plurality of polarization matrices associated with a plurality of target positions of a target wafer substrate and configured to generate a plurality of reduction result data through dimension reduction of one or more elements of each of the plurality of polarization matrices; and
a map generator configured to generate a wafer map associated with the target wafer substrate based on the plurality of reduction result data.

2. The wafer map generation device of claim 1, wherein the map generator is configured to generate the wafer map by mapping one component of first reduction result data among the plurality of reduction result data to a first mapping position of the wafer map.

3. The wafer map generation device of claim 2, wherein the first reduction result data correspond to a first target position among the plurality of target positions.

4. The wafer map generation device of claim 2, wherein the map generator is configured to scale the one component of the first reduction result data so as to be mapped to the first mapping position, instead of mapping the one component to the first mapping position.

5. The wafer map generation device of claim 3, wherein the dimension reducer is configured to generate the first reduction result data by performing dimension reduction on one or more elements of a first polarization matrix among the plurality of polarization matrices.

6. The wafer map generation device of claim 5, wherein the first polarization matrix corresponds to the first target position.

7. The wafer map generation device of claim 1, wherein
the plurality of polarization matrices respectively correspond to the plurality of target positions, and
the dimension reducer is configured to generate the plurality of reduction result data by performing dimension reduction on elements placed at one or more rows and one or more columns from each of the plurality of polarization matrices.

8. The wafer map generation device of claim 7, wherein the dimension reducer is configured to:
select the elements placed at the one or more rows and the one or more columns from each of the plurality of polarization matrices, the selecting the elements based on dimension reduction information; and
select an algorithm for the dimension reduction.

9. The wafer map generation device of claim 8, wherein the algorithm for the dimension reduction includes at least one of a principle component analysis (PCA) algorithm, a t-distributed stochastic neighbor embedding (t-SNE) algorithm, and a uniform manifold approximation and projection (UMAP) algorithm.

10. The wafer map generation device of claim 7, wherein
the plurality of reduction result data respectively correspond to the plurality of target positions, and
the map generator is configured to generate the wafer map by mapping one or more component of each of the plurality of reduction result data to a corresponding mapping position of the wafer map.

11. The wafer map generation device of claim 10, wherein the map generator is configured to select one or more components from each of the plurality of reduction result data based on map generation information, or is configured to determine whether to scale the one or more components.

12. The wafer map generation device of claim 1, wherein
an element of each of the plurality of polarization matrices has dimension 1×K (K being an integer of 2 or more),
each of the plurality of reduction result data has dimension 1×J (J being an integer of 2 or more), and
“J” is less than or equal to “K”.

13. The wafer map generation device of claim 1, wherein the plurality of polarization matrices indicate polarization states of a plurality of lights reflected from the plurality of target positions.

14. The wafer map generation device of claim 13, wherein the plurality of polarization matrices are generated based on obtaining a plurality of second lights associated with the plurality of target positions after emitting a plurality of first lights with a plurality of wavelength bands and a plurality of polarization states to the plurality of target positions, respectively.

15. The wafer map generation device of claim 13, wherein each of the plurality of polarization matrices includes at least one of a Mueller matrix and a Jones matrix.

16. A method of operating a wafer map generation device, the method comprising:
receiving a plurality of polarization matrices associated with a plurality of target positions of a target wafer substrate;
generating a plurality of reduction result data through dimension reduction of one or more elements of each of the plurality of polarization matrices; and
generating a wafer map associated with the target wafer substrate based on the plurality of reduction result data.

17. The method of claim 16, further comprising:
identifying a first value and a second value, the first value corresponding to a maximum value among values of the wafer map and the second value corresponding to a minimum value among values of the wafer map; and
generating additional information for fine measurement of the target wafer substrate based on the first value and the second value.

18. A method of operating a wafer map generation device, the method comprising:
sequentially stacking a plurality of layers on a wafer substrate; and
generating a plurality of wafer maps corresponding to a plurality of target wafer substrates by setting the wafer substrate as a target wafer substrate whenever one layer is completely stacked on the wafer substrate,
wherein the generating of the plurality of wafer maps includes,
receiving a plurality of polarization matrices associated with a plurality of target positions of each of the plurality of target wafer substrates,
generating a plurality of reduction result data through dimension reduction of one or more elements of each of the plurality of polarization matrices, and
generating the plurality of wafer maps respectively associated with the plurality of target wafer substrates and based on the plurality of reduction result data.

19. The method of claim 18, further comprising:
detecting abnormal process positions based on the plurality of wafer maps.

20. The method of claim 18, further comprising:
detecting abnormal process steps based on defective chip position information and the plurality of wafer maps.
